(19) United States
(12) Patent Application Publication
(10) Pub. No.: US 2011/0303899 A1
(43) Pub. Date: Dec. 15, 2011

(54) GRAPHENE DEPOSITION

(75) Inventors: Deenesh Padhi, Sunnyvale, CA (US); Jacob Janzen, Redwood City, CA (US); Shahid Shaikh, Santa Clara, CA (US); Bok Hoen Kim, San Jose, CA (US); Barry Chin, Saratoga, CA (US)

(73) Assignee: Applied Materials, Inc., Santa Clara, CA (US)

(21) Appl. No.: 13/158,186

(22) Filed: Jun. 10, 2011

Related U.S. Application Data
(60) Provisional application No. 61/353,594, filed on Jun. 10, 2010.

(51) Int. Cl. H01L 21/20; H01L 29/16

(52) U.S. Cl. 257/29; 438/478; 257/E21.09; 257/E29.082

(57) ABSTRACT

Embodiments of the invention are directed toward the deposition of Graphene on a semiconductor substrate. In some embodiments, these processes can occur at low temperature levels during a back end of the line process. For example, Graphene can be deposited in a CVD reactor at a processing temperature that is below 600° C. to protect previously deposited layers that may be susceptible to sustained higher temperatures. Graphene deposition can include the deposition of an underlayer (e.g., cobalt) followed by the flow of a carbon precursor (e.g., acetylene) at the processing temperature. Graphene can then be synthesized with during cooling, an RTP cure, and/or a UV cure.

### CROSS-REFERENCES TO RELATED APPLICATIONS

This application is a non-provisional, and claims the benefit, of commonly assigned U.S. Provisional Application No. 61/353,594, filed Jun. 10, 2010, entitled “Manufacturable Large Area Deposition of Graphene For CMOS,” the entirety of which is herein incorporated by reference for all purposes.

### BACKGROUND

Graphene has long been considered an ideal material for semiconductors due to its high carrier mobility. The difficulty, however, is that graphene can be difficult to produce on a substrate. Various techniques have been proposed without much success. While these techniques have been developed in the lab, none have proven scalable for device production.

### BRIEF SUMMARY

Embodiments of the invention are directed toward the deposition of Graphene on a semiconductor substrate. In some embodiments, these processes can occur at low temperature levels during a back end of the line process. For example, Graphene can be deposited in a CVD reactor at a processing temperature that is below 600° C. to protect previously deposited layers that may be susceptible to sustained higher temperatures. Graphene deposition can include the deposition of an underlayer (e.g., cobalt) followed by the flow of a carbon precursor (e.g., acetylene) at the processing temperature. Graphene can then be synthesized with during cooling, an RTP cure, and/or a UV cure.

A method for depositing Graphene on a substrate is provided according to some embodiments of the invention. In some embodiments, Graphene can be deposited by placing a substrate in a CVD chamber, heating the substrate to a temperature below 600° C. (the processing temperature), and flowing a carbon precursor (e.g., acetylene) into the chamber. In some embodiments, the processing temperature can be below 400° C., 450° C., or 600° C. In some embodiments, Graphene can be synthesized on the substrate by cooling the substrate to a temperature below 100° C. (or to room temperature), using an RTP process, and/or a UV cure process. In some embodiments, Graphene can be deposited over a metallic layer (e.g, copper) and/or over an underlayer (e.g., cobalt and/or nickel).

A substrate with Graphene layers is also provided according to some embodiments of the invention. In some embodiments, the substrate can include a cobalt underlayer deposited on the semiconductor substrate and a Graphene layer deposited on the cobalt underlayer. In some embodiments, a metallic layer can be deposited between the semiconductor substrate and the cobalt underlayer. In some embodiments, the metallic layer has a thickness between 500 \dot{A} and 400 \dot{A} or 50 \dot{A} and 200 \dot{A}. In some embodiments, the metallic layer has a thickness of about 2000 \dot{A}.

Another Graphene deposition method is proved according to some embodiments of the invention. In this embodiment, a metallic underlayer (e.g., cobalt or nickel) is deposited on a semiconductor substrate. The semiconductor substrate is placed within a CVD chamber and the substrate is heated to a processing temperature below 450° C. A carbon precursor is flowed into the chamber and Graphene is synthesized. In some embodiments, Graphene is synthesized by allowing the substrate to cool to a temperature below 100° C., subjecting the substrate to an RTP process, and/or subjecting the substrate to ultraviolet light.

The following detailed description together with the accompanying drawings will provide a better understanding of the nature and advantages of the present invention.

### BRIEF DESCRIPTION OF THE DRAWINGS

FIG. 1 shows an example of a CVD processing chamber that can be used in the various embodiments of the invention.

FIG. 2A shows an example of a Graphene layer used in a Field-Effect Transistor (FET) according to some embodiments of the invention.

FIG. 2B shows a schematic cross-section of the FET shown in FIG. 2A.

FIG. 3 shows an example of layers that can be used for Graphene connect 220 according to some embodiments of the invention.

FIG. 4 is a flowchart of a process for depositing Graphene on s substrate according to some embodiments of the invention.

FIG. 5 is a flowchart of a process for depositing Graphene on a substrate according to another embodiment of the invention.

FIG. 6 shows resistivity as a function of line width for Graphene, Copper, and carbon nano-tubes.

### DETAILED DESCRIPTION

The following disclosure describes in detail various and alternative embodiments of the invention with accompanying drawings. Numerals within the drawings and mentioned herein represent substantially identical structural elements. Each example is provided by way of explanation, and not as a limitation. Modifications and variations can be made. For instance, features illustrated or described as part of one embodiment may be used on another embodiment to yield a further embodiment. Thus, it is intended that this disclosure includes modifications and variations.

Embodiments of the invention are directed toward the deposition of grapheme monolayers at low deposition temperatures; for example, less than 600° C. (or less than 400° C. or less than 450° C.). Embodiments of the invention are also directed toward the deposition of grapheme using plasma enhanced chemical vapor deposition (PECVD) techniques that can include RTP curing and/or UV curing techniques to ensure Graphene synthesis.

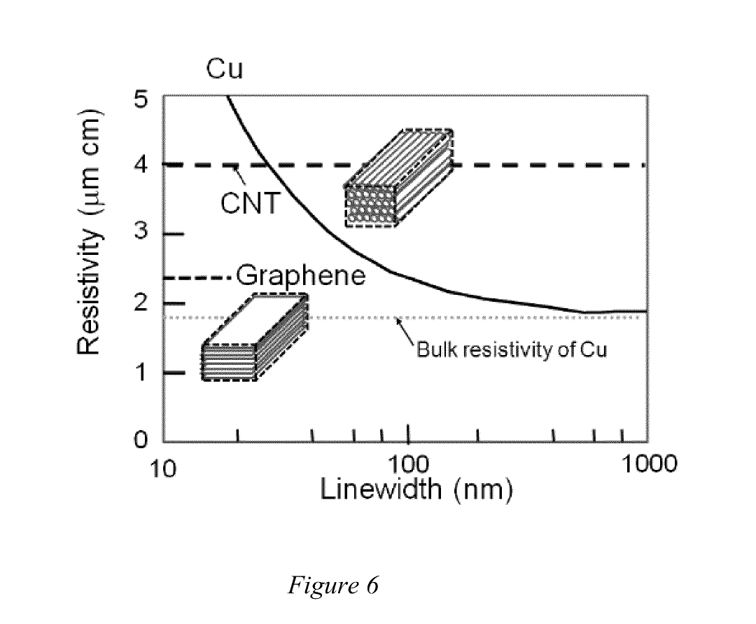

Graphene is an allotrope of carbon; whose generally structure is a one-atom-thick planar sheets of sp²-bonded carbon atoms that are densely packed in a honeycomb crystal lattice. Graphene is an ideal material for semiconductor components because of its low and stable resistivity at small line widths. FIG. 6 shows resistivity as a function of line width for Graphene, Copper, and carbon nano-tubes. As shown in the graph, Graphene has low and constant resistivity regardless of the line width.

CVD Plasma Reactor

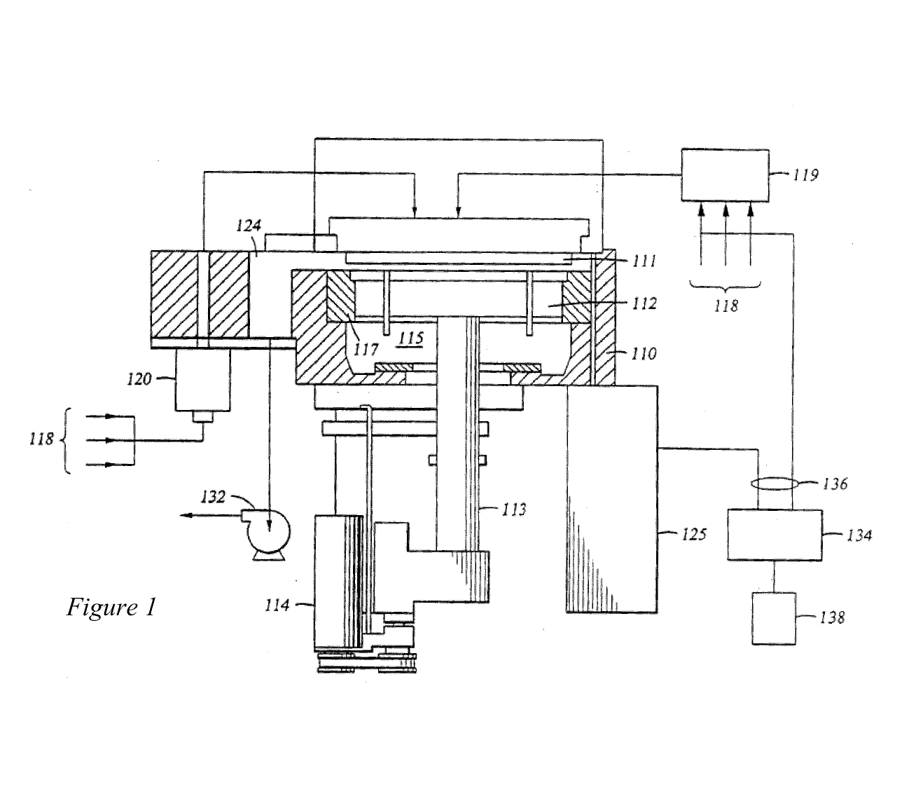

One suitable CVD plasma reactor in which a method of the present invention can be carried out is the “DLK” chamber available from Applied Materials of Santa Clara, Calif., and is shown in FIG. 1, which is a vertical, cross-section view of a parallel plate chemical vapor deposition reactor 110 having a high vacuum region 115. Reactor 110 contains a gas distribution manifold 111 for dispersing process gases through perforated holes in the manifold to a substrate or substrate (not shown) that rests on a substrate support plate or susceptor 112 which is raised or lowered by a lift motor 114. A liquid injection system (not shown), such as typically used for liquid injection of TEOS, may also be provided for injecting a liquid reactant. Preferred liquid injection systems include the AMAT Gas Precision Liquid Injection System (GPLIS) and the AMAT Extended Precision Liquid Injection System (EPLIS), both available from Applied Materials, Inc. Various other CVD or PECVD chambers can be used without limitation.

The reactor 110 includes heating of the process gases and substrate, such as by resistive heating coils (not shown) or external lamps (not shown). Susceptor 112 is mounted on a support stem 113 so that susceptor 112 (and the substrate supported on the upper surface of susceptor 112) can be controllably moved between a lower loading/off-loading position and an upper processing position which is closely adjacent to manifold 111.

When susceptor 112 and the substrate are in processing position, they are surrounded by an insulator 117 and process gases exhaust into a manifold 124. In the specific DLK design shown and described in connection with FIG. 1, the substrate may be seated within a pocket (not shown) in the upper surface of the susceptor, sized to allow a clearance of approximately 2 mm between the edge of the wafer and the pocket wall.

During processing, gases inlet to manifold 111 are uniformly distributed radially across the surface of the substrate. A vacuum pump 132 having a throttle valve controls the exhaust rate of gases from the chamber.

Before reaching manifold 111, deposition and carrier gases are input through gas lines 118 into a mixing system 119 where they are combined and then sent to manifold 111. An optional microwave system 150 having an applicator tube 120 may be located on the input gas line for the oxidizing gas to provide additional energy that dissociates only the oxidizing gas prior to entry to the reactor 110. The microwave applicator provides a power from between about 0 and about 6000 W. Generally, the process gases supply lines 18 for each of the process gases include (i) safety shut-off valves (not shown) that can be used to automatically or manually shut off the flow of process gas into the chamber, and (ii) mass flow controllers (also not shown) that measure the flow of gas through the gas supply lines. When toxic gases are used in the process, several safety shut-off valves are positioned on each gas supply line in conventional configurations.

The deposition process performed in reactor 110 can be either a non-plasma process on a cooled substrate pedestal or a plasma enhanced process. In a plasma process, a controlled plasma is typically formed adjacent to the substrate by RF energy applied to manifold 111 from RF power supply 125 (with susceptor 112 grounded). Alternatively, RF power can be provided to the susceptor 112 or RF power can be provided to different components at different frequencies. RF power supply 125 can supply either single or mixed frequency RF power to enhance the decomposition of reactive species introduced into the high vacuum region 115. A mixed frequency RF power supply typically supplies power at a high RF frequency (RF1) of about 13.56 MHz to the manifold 111 and at a low RF frequency (RF2) of about 360 KHz to the susceptor 112. The silicon oxide layers of the present invention are most preferably produced using low levels or pulsed levels of high frequency RF power. Pulsed RF power preferably provides 13.56 MHz RF power at about 20 to about 200 W during about 10% to about 30% of the duty cycle. Non-pulsed RF power preferably provides 13.56 MHz RF power at about 10 to about 150 W as described in more detail below. Low power deposition preferably occurs at a temperature range from about −20 to about 40° C. At the preferred temperature range, the deposited film is partially polymerized during deposition and polymerization is completed during subsequent curing of the film.

When additional dissociation of the oxidizing gas is desired, an optional microwave chamber can be used to input from about 0 to about 3000 W of microwave power to the oxidizing gas prior to entering the deposition chamber. Separate addition of microwave power would avoid excessive dissociation of the silicon compounds prior to reaction with the oxidizing gas. A gas distribution plate having separate passages for the silicon compound and the oxidizing gas is preferred when microwave power is added to the oxidizing gas.

Typically, any or all of the chamber lining, gas inlet manifold faceplate, support stem 113, and various other reactor hardware is made out of material such as aluminum or anodized aluminum. An example of such a CVD reactor is described in U.S. Pat. No. 5,000,113, entitled “Thermal CVD/PECVD Reactor and Use for Thermal Chemical Vapor Deposition of Silicon Dioxide and In-situ Multi-step Planarized Process,” issued to Wang et al. and assigned to Applied Materials, Inc., the assignee of the present invention.

The lift motor 114 raises and lowers susceptor 112 between a processing position and a lower, substrate-loading position. The motor, the gas mixing system 119, and the RF power supply 125 are controlled by a system controller 134 over control lines 136. The reactor includes analog assemblies, such as mass flow controllers (MFCs) and standard or pulsed RF generators that are controlled by the system controller 134 which executes system control software stored in a memory 210, which in the preferred embodiment is a hard disk drive. Motors and optical sensors are used to move and determine the position of movable mechanical assemblies such as the throttle valve of the vacuum pump 132 and motor for positioning the susceptor 112.

The system controller 134 controls all of the activities of the CVD reactor and a preferred embodiment of the controller 134 includes a hard disk drive, a floppy disk drive, and a card rack. The card rack contains a single board computer (SBC), analog and digital input/output boards, interface boards and stepper motor controller boards. The system controller conforms to the Versa Modular Europeans (VME) standard which defines board, card cage, and connector dimensions and types. The VME standard also defines the bus structure having a 16-bit data bus and 24-bit address bus.

Graphene Transistors

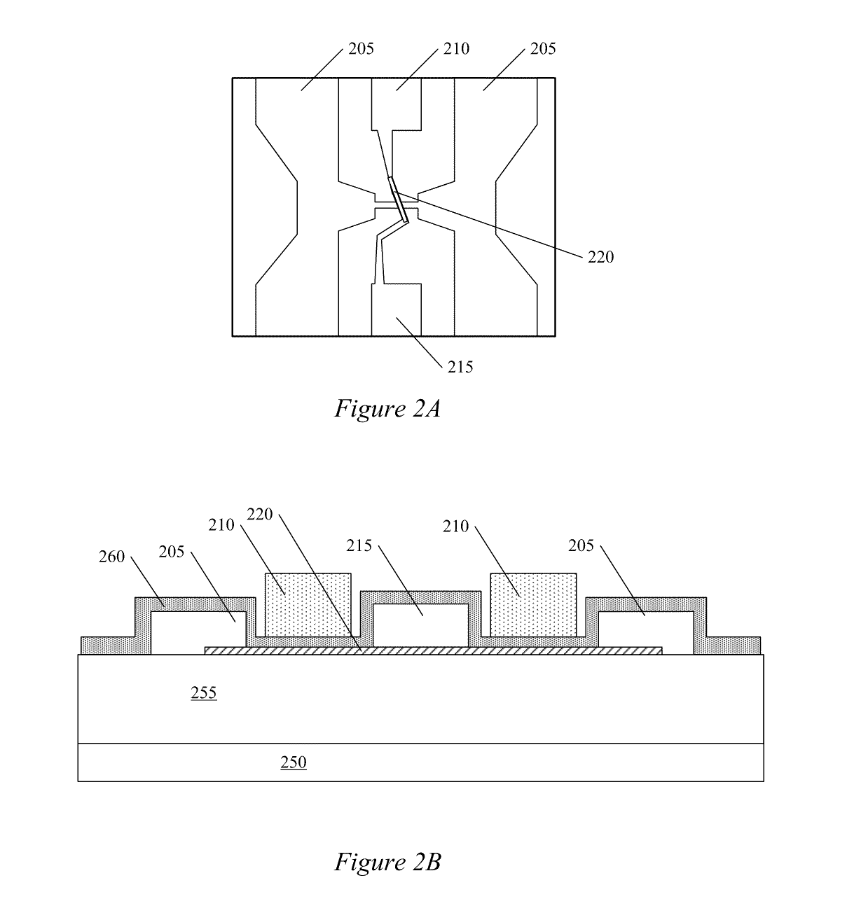

Embodiments of the invention can be used to deposit Graphene layers for a number of applications. FIG. 2A shows an example of Graphene layer 220 used in a Field-Effect Transistor (FET). In this example, Graphene connect 220 is used to connects gate 210 with drain 215 between the sources 205. FIG. 2B shows a schematic cross-section of the FET shown in FIG. 2A. Graphene connect 220 is deposited on substrate 255 that can include SiO₂ 255, and/or on high resistivity silicon 250. Any other substrate material can be used. Sources 205 and drain 215 are separated from gate 210 with oxide layer 260.

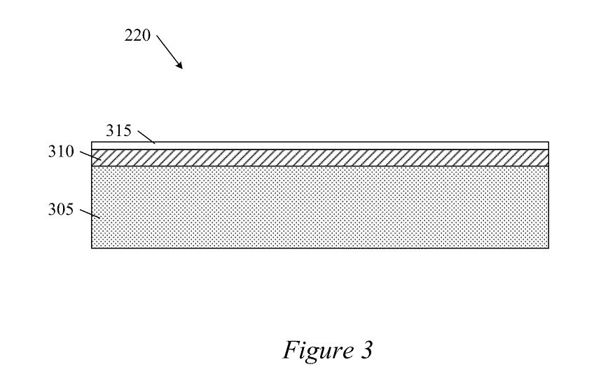

In some embodiments, Graphene connect 220 can include multiple layers. FIG. 3 shows an example of layers that can be used for Graphene connect 220 according to some embodiments of the invention. Graphene connect can include metallic base layer 305, underlayer 310, and Graphene 315. Metallic base layer 305 can include any conductive metal such as, for example, copper. Metallic layer 305 can be deposited directly on a semiconductor substrate. Metallic layer can have a thickness, for example, of 500-4000 \dot{A}. In one specific embodiment, metallic layer 305 can have a thickness of about 2000 \dot{A}.

Underlayer 310 can have a thickness of about 20-500 \dot{A}. In one specific embodiment, underlayer 310 can have a thickness of 50-200 \dot{A}. Underlayer 302 can include a metal with low activation energy and/or with voids. These voids can break the precursor molecule and absorb carbon from the precursor. For example, underlayer 310 can include cobalt and/or nickel. Graphene 315 can be formed on underlayer 310. Graphene 315 can comprise one to many Graphene layers.

Graphene Deposition

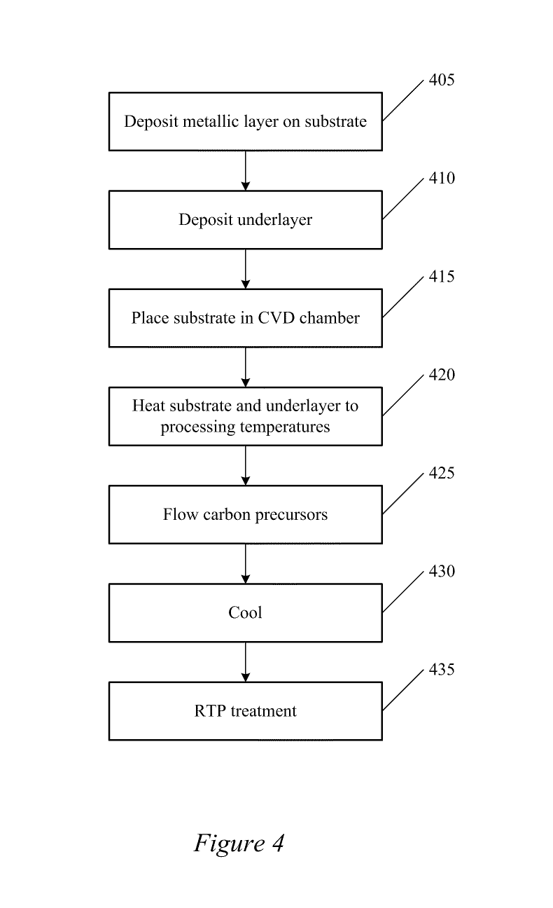

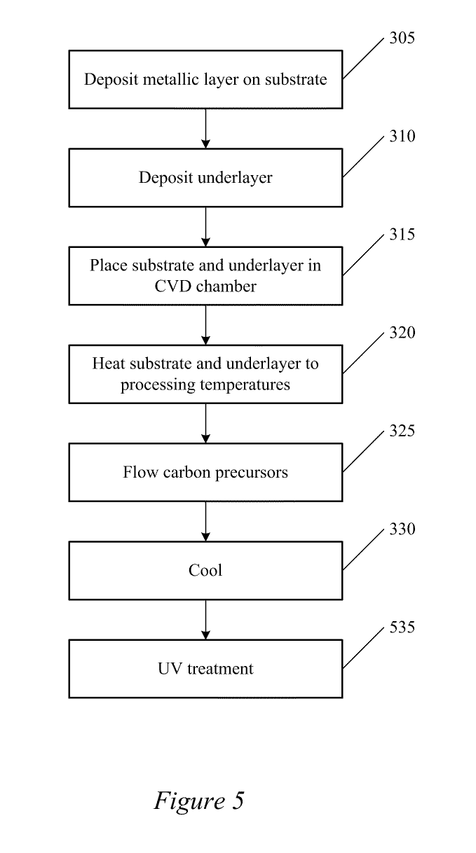

Graphene can be deposited on a substrate using various processes such as those shown in FIG. 4 and/or FIG. 5. Turning first to FIG. 4. A flowchart of a process for depositing Graphene on a substrate is shown. At block 405, a metallic layer (e.g., metallic layer 305) is deposited on the substrate. This metallic layer, for example, can include copper or any other metal with a high electrical conductivity. This metallic layer can be an interconnect between a source and a drain as shown in FIG. 2A or any other interconnect. This metallic layer can be deposited to a thickness of 500-4000 \dot{A}. For example, the metallic layer can have a thickness of about 2000 \dot{A}. Various other thickness can be used. And this layer can be deposited using any deposition technique known in the art. The metallic layer can be deposited on substrate 255 shown in FIG. 2B.

At block 410 an underlayer (e.g., underlayer 310) can be deposited on the metallic layer. This underlayer can be selectively deposited only on the metallic layer deposited at block 405. In some embodiments, the underlayer is not deposited on dielectric layers. In some embodiments, any number of deposition techniques can be used to ensure that the underlayer is deposited solely on the metallic layer. This underlayer can include cobalt, nickel, or any other material with low activation energy. In some embodiments, materials that break down precursor molecules and absorb carbon can particularly beneficial for the underlayer. The underlayer can have a thickness of about 20-500 \dot{A}. Or, more specifically the underlayer can have a thickness of 50-200 \dot{A}.

At block 415 the substrate with the metallic and/or underlayer are placed in a CVD reactor (e.g., reactor 110 shown in FIG. 1). The substrate can be placed, for example, on susceptor 112.

At block 420 the substrate can be heated to a deposition a processing temperature. This processing temperature, for example, at a temperature between 400° C. and 1000° C. In other examples, the processing temperature can be less than 600° C., less than 500° C., less than 450° C., less than 400° C., or less than 350° C. In some embodiments, it can be beneficial to keep the processing temperature low because the Graphene is deposited as part of the back end of the line (BEOL) process. That is, Graphene may be deposited after many other layers have been deposited. Because some previously deposited layers may be sensitive to high, sustained temperatures it can be beneficial to perform Graphene deposition at low temperatures in order to avoid damaging these previously deposited layers.

In some embodiments, the underlayer is deposited solely on the metallic layer and not on any surrounding material (such as dielectrics). Because of this, in such embodiments, the Graphene is deposited only on the copper layers as well.

After the substrate and layers have been raised to the processing temperature, a carbon precursor can be flowed into the processing chamber at block 425. Various carbon based precursors can be used. A hydrocarbon such as CₓH_{y} can be used, where 1≦x≦10 and 2≦y≦20. Acetylene is an example of such a hydrocarbon. Various halogenated hydrocarbons can also be used such as CCl₄ or CH₂I₂. The carbon precursor can be flowed into the processing chamber for 5-10 minutes. The carbon precursor can be flowed into the chamber at various flow rates. For example, the carbon precursor can flow into the chamber, for example, at 10 sccm to 10,000 sccm. As another example, the flow rate can vary from 500 sccm to 2000 sccm. The amount of time the carbon precursor is flowed into the chamber can depend on the temperature of the processing chamber, the precursor flow rate, the size of the chamber, etc. The precursor can flow in the chamber with a diluent gas (e.g., H₂, He, Ar, NH₃, N₂, etc). The diluent gas can flow into the chamber with a flow rate of 10 sccm to 10,000 sccm. As another example, the flow rate can vary from 500 sccm to 2000 sccm.

In some embodiments, the chamber can be under pressure during precursor flow. For example, the chamber can have a pressure of 10 mT to 600 Ton. As another example, the spacing can vary between 5 Ton and 20 Torr. Moreover, the spacing between the showerhead and the substrate can vary. For example, the spacing can vary, for example, between 50 mils to 2000 mils. As another example, the spacing can vary between 300 mils to 600 mils.

After the carbon precursor has been flowed into the processing chamber, the substrate can be cooled to a temperature below 100° C. at block 430. For example, the substrate can be cooled to a temperature around room temperature (e.g. 15° C.-25° C.). During cooling, carbon molecules can seep from within voids in the underlayer forming Graphene on top of the underlayer. In some embodiments, a rapid thermal process (RTP) can be used to aide in this Graphene synthesis. For example, the Graphene and/or the other layers can be heated to over 1200° C. for a few milliseconds. In some embodiments, the substrate can be heated to a temperate over 1000° C. This RTP process can occur within the CVD chamber or within another chamber.

The RTP process can be a dynamic surface anneal process. For example, the RTP process can use a milli-second pulsed laser to anneal the Graphene. The Applied Vantage Astra device produced by Applied Materials can be used. Such devices, or similar devices, can ramp to high temperatures from low preheat temperatures very quickly and then cool down very quickly. This can reduce various manufacturing defects that may occur.

FIG. 5 is a flowchart of a process for depositing Graphene on a substrate according to another embodiment of the invention. This process is similar to the process shown in FIG. 4, except block 435 is replaced with block 535. At block 535, Graphene synthesis can be aided by a UV cure. That is, the Graphene layer can be exposed to ultraviolet radiation for a period of time. Various other processes can be used to aide in Graphene synthesis. In some embodiments, both an RTP process (e.g., block 435 of FIG. 4) and a UV cure (e.g., block 535 of FIG. 5) can be used to aide in Graphene synthesize.

The various processes, blocks, or steps shown in FIG. 4 or FIG. 5 can occur in any order. Moreover, any of the processes, blocks, or steps can be omitted. For example, in some embodiments, block 415 can occur prior to block 410 and/or block 405. That is, in some embodiments, the metallic and/or underlayer deposition processes can occur within the same CVD chamber as the other processes. In some embodiments, these processes can occur in separate chambers.

Thus, although the invention has been described with respect to specific embodiments, it will be appreciated that the invention is intended to cover all modifications and equivalents within the scope of the following claims. The present disclosure has been presented for purposes of example rather than limitation, and does not preclude inclusion of such modifications, variations and/or additions to the present subject matter as would be readily apparent to one of ordinary skill in the art.

1. A method for depositing graphene on a substrate, the method comprising:
placing a substrate in a CVD chamber;
heating the substrate to a temperature below 600° C.; and
flowing a carbon precursor into the chamber.

2. The method according to claim 1 further comprising cooling the substrate to a temperature below 100° C. to allow Graphene to form on the substrate.

3. The method according to claim 2 further comprising exposing the substrate to a temperature greater than 1000° C. for a few milliseconds.

4. The method according to claim 2 further comprising exposing the substrate to ultraviolet radiation.

5. The method according to claim 1, where the substrate is heated to a temperature below 450° C.

6. The method according to claim 1 further comprising annealing the substrate with a millisecond laser process.

7. The method according to claim 1, wherein the carbon precursor comprises acetylene.

8. The method according to claim 1 further comprising depositing a metallic layer prior to heating the substrate.

9. The method according to claim 8 wherein carbon precursor comprises CₓH_{y} where 1≦x≦10 and 2≦y≦20.

10. The method according to claim 1 further comprising depositing an underlayer prior to heating the substrate.

11. The method according to claim 8 wherein the metallic underlayer comprises either cobalt or nickel.

12. A semiconductor device comprising:
semiconductor substrate;
a cobalt underlayer deposited on the semiconductor substrate; and
a Graphene layer deposited on the cobalt underlayer.

13. The semiconductor device according to claim 12, further comprising a metallic layer deposited between the semiconductor substrate and the cobalt underlayer.

14. The semiconductor device according to claim 13, wherein the metallic layer has a thickness between 500 \dot{A} and 400 \dot{A}.

15. The semiconductor device according to claim 13, wherein the metallic layer has a thickness of about 2000 \dot{A}.

16. The semiconductor device according to claim 12, wherein the cobalt underlay has a thickness between 50 \dot{A} and 200 \dot{A}.

17. A method for depositing graphene on a substrate, the method comprising:
depositing a metallic underlayer on a semiconductor substrate;
placing the semiconductor substrate in a CVD chamber;
heating the substrate to a temperature below 450° C.;
flowing a hydrocarbon precursor into the chamber; and
synthesizing Graphene.

18. The method according to claim 17, where synthesizing Graphene further comprises:
allowing the substrate to cool to a temperature below 100° C.; and
subjecting the substrate to an RTP process.

19. The method according to claim 17, where synthesizing Graphene further comprises:
allowing the substrate to cool to a temperature below 100° C.; and
subjecting the substrate to ultraviolet light.

20. The method according to claim 17, wherein the metallic underlayer comprises either or both copper or nickel.
